(19) United States
(12) Patent Application Publication
(10) Pub. No.: US 2009/0146166 A1
(43) Pub. Date: Jun. 11, 2009

(54) Structure Applying Optical Limit Guide Layer

(76) Inventors: Cheng-yi Liu, Jhongli City (TW); Yung-Hsun Lin, Jhongli City (TW); Ching-Liang Lin, Jhongli City (TW); Po-Han Chen, Jhongli City (TW); Chia-Lun Chang, Jhongli City (TW); Pen-Ko Chou, Jhongli City (TW); Yi-Ju Chen, Jhongli City (TW); You-Hsian Chang, Jhongli City (TW)

Correspondence Address: HDLS Patent & Trademark Services, P.O. BOX 220746, CHANTILLY, VA, 20153-0746, US

(21) Appl. No.: 12/060,878

(22) Filed: Apr. 2, 2008

(30) Foreign Application Priority Data
Dec. 5, 2007 (TW) 096146315

(51) Int. Cl. H01L 33/00; F21V 8/00

(52) U.S. Cl. 257/98; 362/555; 257/E33.068

(57) ABSTRACT

A structure applying an optical wave guide layer includes an incident light source and at least one optical wave guide layer. The structure can be in any geometric shape such as a planar, hemispherical or conical shape. The geometric structure is designed for collecting and guiding the incident light source in specific directions. The light can be guided by a combination of materials having different optical properties. The incident angle of the collected light is controlled and the materials are selected to effectively overcome a drawback of the prior art that a portion of the light of some optical components cannot be extracted by a light extraction method.

### FIELD OF THE INVENTION

The present invention relates to a structure applying an optical wave-guide layer with LED (Light Emitting Diode), and more particularly to a structure using a combination of materials with different optical properties to collect incident light and effectively guide the collected incident light to outside ambient to effectively overcome a drawback of the prior art optical component that loss a portion of the light by reflection loss, absorption, and limitation of the light extraction method.

### BACKGROUND OF THE INVENTION

The optoelectronic industry relates to all business conducts including the manufacture or application of optoelectronic components, and the equipment, tools, and systems that adopt optoelectronic components as key component modules.

As defined by the Optoelectronic Science and Technology Association, the optoelectronic industry is divided into six main categories, respectively: optoelectronic component, optical display, optical input/output, optical storage, optical communication, laser and other optoelectronic applications.

The aforementioned optoelectronic components can be applied to a light-to-electricity converter (or a solar cell), an optical fiber communication, an optical information storage device (such as a laser CD), an optical display and an optical detector.

In the case of LED device, the light loss would happen as follows:

1. Absorption loss: As light emitted from the light emitting layer, it need to pass through several cladding layers before escaping outer ambient. Portion of the emitting light could be absorbed.

2. Reflectivity loss: Generally, when light emitted from light emitting layer. For some particular LED structures, such as, flip-chip and thin-GaN LED, a mirror reflector is used to reflect either upward or downward light. The reflecting light would have certain degree of loss due to the reflectivity.

3. The total-reflection loss: As the emitting light arrive the top surface of LED device (usually III V compound surface), the totally reflection behavior would happen. A significant emitting light would be lost and confined in the LED chip. Only small portion of emitting light can be extracted toward the outer ambient.

It is a subject for manufacturers to develop a new technology to prevent the reflectivity loss, absorption loss, and the totally reflection loss on the top emitting surface, so as to promote the development and advancement of the industry.

### SUMMARY OF THE INVENTION

In view of the foregoing shortcomings of the light extraction method adopted by a conventional optoelectronic component that still cannot obtain a portion of light, the inventor of the present invention based on years of experience in the related industry to conduct extensive researches and experiments to overcome the shortcomings of the prior art, and finally developed a structure applying an optical wave guide layer in accordance with the present invention.

The primary objective of the present invention is to provide a novel structure applying an optical wave guide layer, adopt a combination of materials having different optical properties, and apply the structure of the optical limit guide layer for guiding the collected incident emitting light. The invention collects the incident emitting light and the effectively prevent the conventional optoelectronic component from being unable of obtaining a portion of the light by the conventional light extraction method. Obviously, the structure of the invention is valuable to the applications in the related industries, such as LED.

### BRIEF DESCRIPTION OF THE DRAWING

FIG. 1 is a schematic view of a basic structure of an optical wave guide layer in accordance with the present invention; and

FIG. 2 is a schematic view of a manufacturing procedure of applying a structure having an optical limit guide layer to a thin GaN LED in accordance with the present invention.

### DETAILED DESCRIPTION OF THE PREFERRED EMBODIMENTS

To make it easier for our examiner to understand the technical measures and operating procedure of the invention, we use a preferred embodiment together with the attached drawings for the detailed description of the invention.

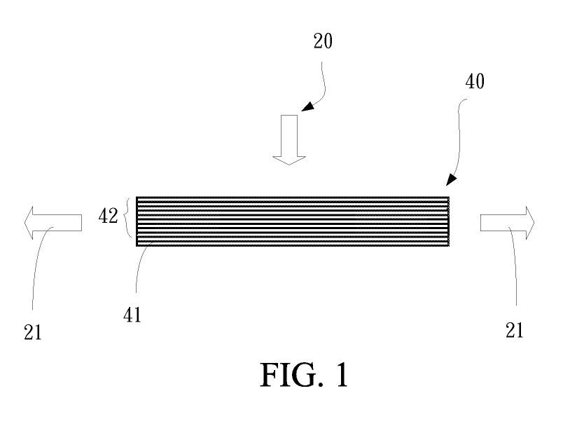

The invention relates to a structure applying an optical wave guide layer. Referring to FIG. 1 for a schematic view of a basic structure of an optical wave guide layer in accordance with the present invention, the structure comprises an incident light source 20 and at least one optical wave guide layer 40, and the structure can be in any geometric shape such as a planar, hemispherical or conical shape, and the structure designed in any geometric shape can collect and guide the incident light source 20 in a specific direction (which is the light guiding direction 21 indicated by the horizontal arrow in FIG. 1).

In this invention, the incident light source 20, and at least one optical wave guide layer 40 can be a single-layer film 41 or a multilayer film 42, wherein the single-layer film 41 can be disposed on a continuous surface or an orderly arranged non-discontinuous surface (such as photonic crystal array), and the single-layer film 41 is made of a material with a high light penetrability (such as silicon dioxide, silicon nitride, aluminum nitride, indium tin oxide, zinc oxide, cadmium oxide, aluminum oxide, zinc sulfide, magnesium oxide, cerium oxide, niobium oxide and epoxy resin). The multilayer film 42 can be made of a composition of materials with different refractive indexes and a high light penetrability (such as silicon dioxide, silicon nitride, aluminum nitride, indium tin oxide, zinc oxide, cadmium oxide, aluminum oxide, zinc sulfide, magnesium oxide, cerium oxide, niobium oxide and epoxy resin), and the materials with different refractive indexes are arranged orderly according to the magnitude of the refractive indexes.

With the foregoing structure, the incident light source 20 can be collected, and the collected light can be guided in any other directions (by simply changing the installation direction of at least one optical limit guide layer 40).

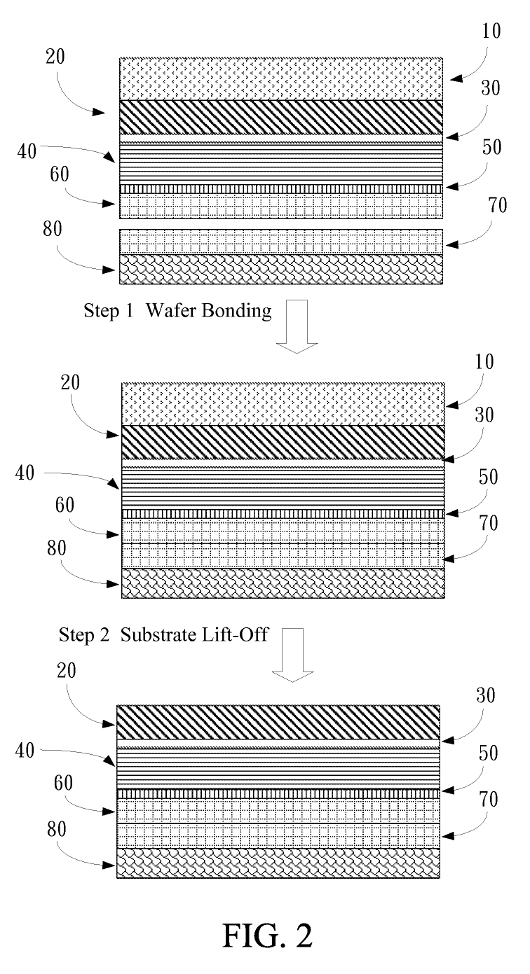

Referring to FIG. 2 for a preferred embodiment of the present invention, the structure of the optical limit guide layer 40 is applied to a manufacturing process of a thin GaN LED, and the manufacturing process comprises the following steps:

Step 1 (Wafer bonding): An e-gun evaporator is used for forming an epitaxy made of a Group III˜V material (such as gallium nitride, AlGaN-based ternary compound, aluminum nitride, InGaN-based ternary compound, AlGaInN-based quaternary compound, indium nitride, GaInAsN-based quaternary compound and GaInPN-based quaternary compound) on the surface of an epitaxial layer of an epitaxial substrate 10 (such as sapphire substrate, silicon carbide substrate, zinc oxide substrate and gallium nitride substrate). In the embodiment of the thin GaN LED, the Group III˜V material is an incident light source 20, and a p-type contact metal layer 30 (such as nickel oxide), the optical limit guide layer 40, an electrode layer 50 (such as aluminum and silver), a first bonding metal layer 60, a second bonding metal layer 70 and a high-performance heat dissipating substrate 80 (such as silicon, aluminum nitride, beryllium oxide, copper) is plated onto a surface of the Group III˜V material by a physical deposition method.

Step 3 (Substrate Lift-Off): A substrate lift-off technology (such as laser lift-off) is provided for removing the epitaxial substrate 10.

The epitaxial substrate 10 serves as a substrate for growing the epitaxial layer to produce a good-quality epitaxial layer. The Group III˜V material is used as the main composition of the components. The p-type contact metal layer 30 is provided for reducing the contact energy barrier to improve the using efficiency of the optoelectronic components. The optical limit guide layer 40 is the main technical characteristic of the present invention, which is provided for guiding the incident light source 20 in a specific direction to prevent the occurrence of a common full reflection or absorption that will affect the light extraction efficiency, and the optical limit guide layer 40 can be a single-layer film 41 or a multilayer film 42 (as shown in FIG. 1), wherein the single-layer film 41 is disposed on a continuous surface or an orderly arranged non-continuous surface (such as a photonic crystal array), and the single-layer film 41 is made of a material with a high light penetrability (such as silicon dioxide, silicon nitride, aluminum nitride, indium tin oxide, zinc oxide, cadmium oxide, aluminum oxide, zinc sulfide, magnesium oxide, cerium oxide, niobium oxide and epoxy resin). The multilayer film 42 can be made of a composition of materials with different refractive indexes and a high light penetrability (such as silicon dioxide, silicon nitride, aluminum nitride, indium tin oxide, zinc oxide, cadmium oxide, aluminum oxide, zinc sulfide, magnesium oxide, cerium oxide, niobium oxide and epoxy resin), and the compositions of materials with different refractive indexes are arranged according to the magnitude of the refractive index.

The electrode layer 50 serves as a reflecting layer, which is also an electrode of the optoelectronic component, and has the functions of conducting and reflecting a light source. The first bonding metal layer 60 and the second bonding metal layer 70 are materials applied in the wafer bonding process for bonding the metal bonds into one. The high-performance heat dissipating substrate 80 is provided for eliminating the high heat produced during the operation of components to facilitate a stable operation of components.

In summation of the description above, the structure of the optical limit guide layer 40 in accordance with the present invention uses a combination of materials having different optical properties to collect and guide lights, controls the incident angle of the collected light, and selects materials to effectively overcome the shortcoming of the conventional light extraction method for optoelectronic components that cannot obtain a portion of the light. Therefore, any structure capable of collecting an incident light source 20 and guiding the collected light in any direction falls within the scope of the present invention. The present invention complies with the requirements of patent application, and the structure of the invention is valuable to the applications in the related industries (such as LED manufacturing factories, packaging factories and optoelectronic semiconductor packaging factories). Thus, the invention is duly filed for patent application.

While the invention has been described by way of example and in terms of a preferred embodiment, it is to be understood that the invention is not limited thereto. To the contrary, it is intended to cover various modifications and similar arrangements and procedures, and the scope of the appended claims therefore should be accorded the broadest interpretation so as to encompass all such modifications and similar arrangements and procedures.

What is claimed is:

1. A structure applying an optical limit guide layer, comprising:
an incident light source; and
at least one optical limit guide layer, plated onto a side of the incident light source by a physical deposition method, for collecting the incident light source and guiding light in specific directions.

2. The structure applying an optical limit guide layer as recited in claim 1, wherein the incident light source and the at least one optical limit guide layer are in any geometric shape.

3. The structure applying an optical limit guide layer a recited in claim 2, wherein the structure designed in any geometric shape guides the incident light source in a specific direction.

4. The structure applying an optical limit guide layer as recited in claim 1, wherein the incident light source is a point light source.

5. The structure applying an optical limit guide layer as recited in claim 1, wherein the incident light source is a line light source.

6. The structure applying an optical limit guide layer as recited in claim 1, wherein the incident light source is a plane light source.

7. The structure applying an optical limit guide layer as recited in claim 1, wherein the at least one optical limit guide layer is a single-layer film.

8. The structure applying an optical limit guide layer as recited in claim 1, wherein the at least one optical limit guide layer is a multilayer film.

9. The structure applying an optical limit guide layer as recited in claim 7, wherein the single-layer film is disposed on a continuous surface.

10. The structure applying an optical limit guide layer as recited in claim 7, wherein the single-layer film is orderly arranged and disposed on a non-continuous surface.

11. The structure applying an optical limit guide layer as recited in claim 7, wherein the single-layer film is made of a material with a high light penetrability.

12. The structure applying an optical limit guide layer as recited in claim 8, wherein the multilayer film is made of a combination of materials with different refractive indexes and a high light penetrability.

13. The structure applying an optical limit guide layer as recited in claim 12, wherein the compositions of materials of different refractive indexes are arranged orderly according to the magnitude of the refractive indexes.

14. A structure applying an optical limit guide layer, comprising:
a Group III˜V material;
a p-type contact metal layer, for plating a surface of the Group III˜V by a physical deposition method;
an optical limit guide layer, for plating a surface of the p-type contact metal layer by a physical deposition method;
an electrode layer, for plating a surface of the optical limit guide layer by a physical deposition method;
a first bonding metal layer, for plating a surface of the electrode layer by a physical deposition method;
a second bonding metal layer, for plating a surface of the first bonding metal layer by a physical deposition method; and
a high-performance heat dissipating substrate, for plating a surface of the second bonding metal layer by a physical deposition method.

15. The structure applying an optical limit guide layer as recited in claim 14, wherein the Group III˜V material is an incident light source.

16. The structure applying an optical limit guide layer as recited in claim 14, wherein the optical limit guide layer is a single-layer film.

17. The structure applying an optical limit guide layer as recited in claim 14, wherein the optical limit guide layer is a multilayer film.

18. The structure applying an optical limit guide layer as recited in claim 16, wherein the single-layer film is disposed on a continuous surface.

19. The structure applying an optical limit guide layer as recited in claim 16, wherein the single-layer film is an orderly arranged and disposed on a non-continuous surface.

20. The structure applying an optical limit guide layer as recited in claim 16, wherein the single-layer film is made of a material with a high light penetrability.

21. The structure applying an optical limit guide layer as recited in claim 17, wherein the multilayer film is made of a composition of materials of different refractive indexes and a high light penetrability.

22. The structure applying an optical limit guide layer as recited in claim 21, wherein the compositions of materials of different refractive indexes are arranged orderly according to the magnitude of the refractive indexes.
